(19) United States
(12) Patent Application Publication
(10) Pub. No.: US 2006/0006515 A1
(43) Pub. Date: Jan. 12, 2006

(54) Conical housing

(76) Inventor: Isaiah Watas Cox, London (GB)

Correspondence Address: Borealis Technical Limited, 23545 NW Skyline Blvd, North Plains, OR, 97133-9204, US

(21) Appl. No.: 11/177,754

(22) Filed: Jul. 8, 2005

(30) Foreign Application Priority Data
Jul. 9, 2004 (GB) GB0415426.6

(51) Int. Cl. H01L 23/06

(52) U.S. Cl. 257/684; 257/678

(57) ABSTRACT

A conical diode device is disclosed, comprising a pair of electrodes and a conical housing. The conical housing ensures that the hermetic seal between the electrodes and the housing remains strong despite thermal imbalances between the two electrodes when the device is in operation. In one embodiment, the conical housing additionally serves as a means for controlling the separation between the electrode pair. In a preferred embodiment, the conical actuating element is a quartz piezo-electric cone. In another embodiment, a modified electrode for use in a diode device of the present invention is disclosed, in which indents are made on the surface of the electrode.

### CROSS-REFERENCE TO RELATED APPLICATIONS

This application claims the benefit of U.K. Provisional Application No. GB0415426.6, filed Jul. 9, 2004.

### BACKGROUND OF THE INVENTION

The present invention relates to diode devices, particularly diode devices for heat pumping or energy conservation.

In U.S. Pat. No. 6,720,704 diode devices are disclosed in which the separation of the electrodes is set and controlled using piezo-electric, electrostrictive or magnetostrictive actuators. This avoids problems associated with electrode spacing changing or distorting as a result of heat stress. In addition it allows the operation of these devices at electrode separations which permit quantum electron tunneling between them. Pairs of electrodes whose surfaces replicate each other are also disclosed. These may be used in constructing devices with very close electrode spacings.

In U.S. Pat. No. 6,417,060 a method for manufacturing a pair of electrodes is disclosed which comprises fabricating a first electrode with a substantially flat surface and placing a sacrificial layer over a surface of the first electrode, wherein the sacrificial layer comprises a first material. A second material is placed over the sacrificial layer, wherein the second material comprises a material that is suitable for use as a second electrode. The sacrificial layer is removed with an etchant, wherein the etchant chemically reacts with the first material, and further wherein a region between the first electrode and the second electrode comprises a gap that is a distance of 50 nanometers or less, preferably 5 nanometers or less. Alternatively, the sacrificial layer is removed by cooling the sandwich with liquid nitrogen, or alternatively still, the sacrificial layer is removed by heating the sacrificial layer, thereby evaporating the sacrificial layer.

In U.S. Pat. No. 6,774,003 a method for manufacturing a pair of electrodes is disclosed which comprises fabricating a first electrode with a substantially flat surface and placing a sacrificial layer over a surface of the first electrode, wherein the sacrificial layer comprises a first material. A second material is placed over the sacrificial layer, wherein the second material comprises a material that is suitable for use as a second electrode. The sacrificial layer is removed with an etchant, wherein the etchant chemically reacts with the first material, and further wherein a region between the first electrode and the second electrode comprises a gap that is a distance of 50 nanometers or less, preferably 5 nanometers or less. Alternatively, the sacrificial layer is removed by cooling the sandwich with liquid nitrogen, or alternatively still, the sacrificial layer is removed by heating the sacrificial layer, thereby evaporating the sacrificial layer.

In U.S. patent application Pub. Ser. No. 2003/0068431 materials bonded together are separated using electrical current, thermal stresses, mechanical force, any combination of the above methods, or any other application or removal of energy until the bonds disappear and the materials are separated. In one embodiment the original bonding was composed of two layers of material. In another embodiment, the sandwich was composed of three layers. In a further embodiment, the parts of the sandwich are firmly maintained in their respective positions during the application of current so as to be able to subsequently align the materials relative to one another.

In U.S. Pat. No. 3,169,200, a multilayer converter is described which comprises two electrodes, intermediate elements and oxide spacers disposed between each adjacent element. A thermal gradient is maintained across the device and opposite faces on each of the elements serve as emitter and collector. Electrons tunnel through each oxide barrier to a cooler collector, thereby generating a current glow through a load connected to the two electrodes. One drawback is that the device must contain some 106 elements in order to provide reasonable efficiency, and this is difficult to manufacture. A further drawback results from the losses due to thermal conduction: although the oxide spacers have a small contact coefficient with the emitter and collector elements, which minimizes thermal conduction, the number of elements required for the operation of the device means that thermal conduction is not insignificant.

In U.S. patent application Pub. Ser. No. 2003/0042819 a thermotunneling converter is disclosed comprising a pair of electrodes having inner surfaces substantially facing one another, and a spacer or plurality of spacers positioned between the two electrodes, having a height substantially equal to the distance between the electrodes, and having a total cross-sectional area that is less than the cross-sectional area of either of the electrodes. In a preferred embodiment, a vacuum is introduced, and in a particularly preferred embodiment, gold that has been exposed to cesium vapor is used as one or both of the electrodes. In a further embodiment, the spacer is made of small particles disposed between the electrodes. In a yet further embodiment, a sandwich is made containing the electrodes with an unoxidized spacer. The sandwich is separated and the spacer is oxidized, which makes it grow to a required height whilst giving it insulatory properties, to allow for tunneling between the electrodes.

In U.S. patent application Pub. Ser. No. 2004/0029341 a gap diode device is disclosed comprising a device containing a material in vapor form between the electrodes, which reduces evaporative losses from the electrode. This method produces devices having improved operating stability and enhanced electrode lifetimes.

The use of composite materials as matching electrode pair precursors is disclosed in U.S. patent application Pub. Ser. No. 2003/0068431. The approach comprises the steps of fabricating a first electrode with a substantially flat surface; placing over the first electrode a second material that comprises a material that is suitable for use as a second electrode, and separating the composite so formed along the boundary of the two layers into two matched electrodes.

In WO03/083177, the use of electrodes having a modified shape and a method of etching a patterned indent onto the surface of a modified electrode, which increases the Fermi energy level inside the modified electrode, leading to a decrease in electron work function is disclosed. FIG. 1 shows the shape and dimensions of a modified electrode 66 having a thin metal film 60 a substrate 62. Indent 64 has a width b and a depth Lx relative to the height of metal film 60. Film 60 comprises a metal whose surface should be as plane as possible as surface roughness leads to the scattering of de Broglie waves. Metal film 60 is given sharply defined geometric patterns or indent 64 of a dimension that creates a De Broglie wave interference pattern that leads to a decrease in the electron work function, thus facilitating the emissions of electrons from the surface and promoting the transfer of elementary particles across a potential barrier. The surface configuration of modified electrode 66 may resemble a corrugated pattern of squared-off, “u”-shaped ridges and/or valleys. Alternatively, the pattern may be a regular pattern of rectangular “plateaus” or “holes,” where the pattern resembles a checkerboard. The walls of indent 64 should be substantially perpendicular to one another, and its edges should be substantially sharp.

In WO03/090245 a Gap Diode is disclosed in which a tubular actuating element serves as both a housing for a pair of electrodes and as a means for controlling the separation between the electrode pair. In a preferred embodiment, the tubular actuating element is a quartz piezo-electric tube. Referring now to FIG. 2, shown is a tubular actuating element 90, having pairs of electrodes 92 disposed on its inner and outer surfaces for controlling the dimensions of the tubular element. FIG. 2 shows three such electrode pairs; fewer or more of such pairs may be present to control the dimensions of the tubular element. WO03/090245 also discloses a schematic process for making a diode device, as shown in FIG. 3, in which in step 300 a first composite 80 is brought into contact with a polished end of a quartz tube 90 of the sort shown in FIG. 2. Composite 80 is preferably a molybdenum disc, which has a similar thermal expansion coefficient as quartz and can be bonded to quartz. In step 310, an electrically conducting paste 94, preferably silver paste, is applied to the upper surface of the molybdenum disc, as shown. In step 320, the polished silicon periphery of the upper composite 78 is contacted with the other polished end of the quartz tube 90. Composite 78 is preferably a matching electrode pair precursor, such as the composite shown in step 130 of WO99/13562 or U.S. Pat. No. 6,417,060, or is more preferably as described in this example, in which a layer of titanium 72 is deposited on substrate 70, and a layer of silver 74 is further deposited on the layer of titanium. A further layer of copper 76 is grown electrochemically on the layer of silver. Most preferably substrate 70 is a silicon wafer, and is polished at least around its periphery where it is in contact with tube 90. At the same time as the upper composite 78 is brought into contact with the end of the quartz tube, the electrically-conducting paste, preferably silver paste or liquid metal, contacts the upper composite as shown. High pressure is applied to this assemblage, which accelerates the chemical reaction between the polished silicon periphery of the composites and the polished ends of the quartz tube, bonding the polished surfaces to form the assemblage depicted in step 320. In step 330, the assemblage is heated, which causes the composite to open as shown, forming a pair of matching electrodes, 72 and 74.

A common feature of the above disclosures is that they comprise diode devices having two electrodes disposed on substrates of similar size positioned at an exact distance from one another. The substrates, and consequently, the electrodes are separated by means of a housing positioned at 90° from the electrodes, which forms a hermetic (i.e. air-tight) seal to the electrodes. However, during operation, The thermal environment of the two electrodes will be dissimilar—one will be hotter relative to the other—and their differential expansion will put a strain on the join between the electrodes and the housing, thereby weakening the hermetic seal. As this seal is crucial for the device to work, there is clearly a need in the art for a device with a different structural design.

### BRIEF SUMMARY OF THE INVENTION

The present invention seeks to solve the problem of thermal imbalances causing stress on the hermetic seal by altering the shape of the device. Accordingly, the present invention discloses a conical housing for a diode device which separates the two substrates having electrodes upon them, and in which one electrode-carrying substrate is significantly larger than the other. The conical housing may be utilized with any of the prior art devices to beneficial effect.

Accordingly, when the substrates expand or contract differentially, the resulting stress on the seal between the housing and the substrates will be reduced.

A further advantage of the present invention is that diode devices having a conical housing are be able to function over a wider range of temperatures than previous devices, and will be able to be constructed from a wider range of materials.

A further advantage of the present invention is that a wider range of materials may be used in the construction of diode devices.

A further significant advantage of this design is that several packaging steps that were needed in previous approaches, such as introducing liquid metal, can be eliminated. The actuator is simply electrically and thermally bonded to the composite, substrate or electrode pair precursor.

### BRIEF DESCRIPTION OF THE SEVERAL VIEWS OF THE DRAWING

For a more complete understanding of the present invention and the technical advantages thereof, reference is made to the following description taken with the accompanying drawings, in which:

FIG. 1 is a cross sectional view of a prior art modified electrode;

FIG. 2 is a diagrammatic representation of one embodiment of a prior art tubular housing/actuator;

FIG. 3 is a schematic showing a prior art process for the manufacture of a diode device having a tubular housing/actuator;

FIG. 4 is a cross sectional view of a conical diode device of the present invention;

FIG. 4 is a cross sectional view of a conical diode device of the present invention, having piezo-electric actuators;

FIG. 6 is a schematic showing a conical diode device of the present invention; and

FIG. 7 is a schematic showing a process for the manufacture of a diode device having a conical housing/actuator.

### DETAILED DESCRIPTION OF THE INVENTION

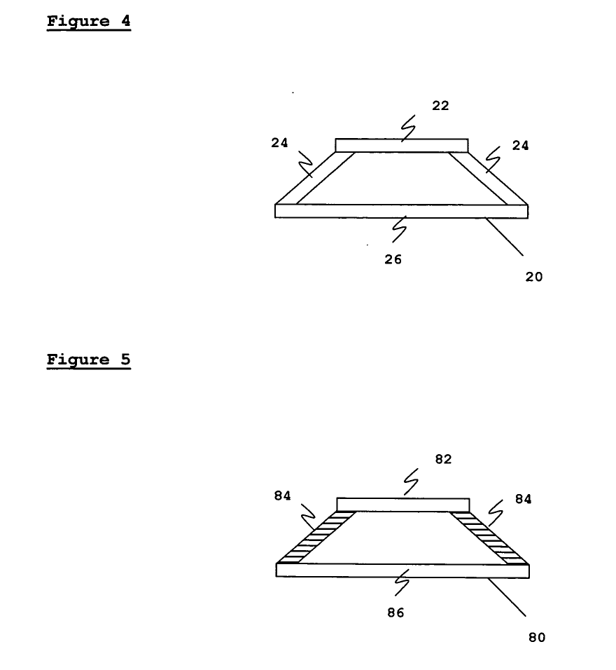

The embodiments of the present invention and its technical advantages are best understood by referring to FIGS. 4-7. The present invention is directed to a conical diode device. It is to be understood that the diode device of the present invention may include a number of types of diode device including, for example, (i) a device which uses a thermal gradient of any kind to generate electrical power using thermionics, thermotunneling or other methods as described herein; (ii) a device which uses electrical power or energy to pump heat, thereby creating, maintaining or degrading a thermal gradient using thermionics, thermotunneling or other methods as described herein; and (iii) as any diode which employs a gap between the anode and the cathode, or between the collector and emitter, and which causes or allows electrons to be transported between the two electrodes, across or through the gap (with or without a vacuum in the gap).

Alternatively, the device of the present invention may be integrated or used for any ordinary diode application.

Referring now to FIG. 4, which shows a diode device 20 of the current invention, a first surface 22 is separated from a second surface 26 by a conical housing 24. Typically first surface 22 is the hot side of the device and second surface 26 is the cold side of the device. Conical housing 24 is hermetically sealed to surfaces 22 and 26, allowing a vacuum or other controlled environment to be formed between the two surfaces.

It is to be understood that diode device 20 can function as a thermionic or thermotunneling converter, or as a thermionic or thermotunneling diode heat pump. Accordingly, surfaces 22 and 26 comprise electrodes made of materials suitable for optimum thermionic or thermotunneling emmission. Accordingly, when device 20 is in operation, electrode 22 expands and electrode 26 contracts. However, because of the cone shape formed by housing 24, there is little or no stress placed on the hermetic seal between walls 24 and electrodes 22 and 26. Thus device 20 will be stronger than previous diode devices, and will accordingly have more possible applications.

The conical housing utilized in the present invention may be formed, for example, of quartz, silicon, silica, metal or glass, the material chosen according to its thermal expansion characteristics under the operating conditions of the diode device. The housing may be beneficially utilized in the diode device configurations of the prior art.

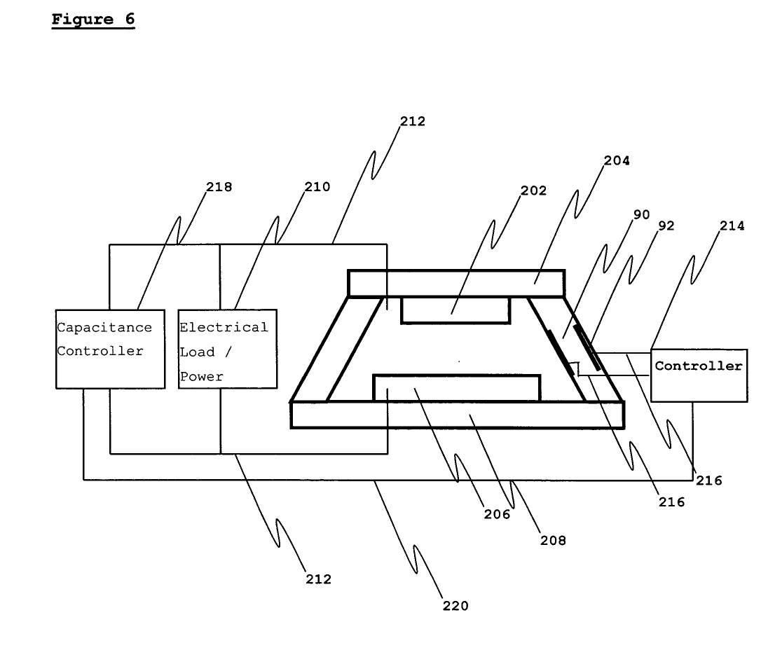

For example, U.S. Pat. No. 6,720,704 discloses diode devices in which the separation of the electrodes is set and controlled using piezo-electric, electrostrictive or magnetostrictive actuators. Thus in a second embodiment of the present invention, the conical housing is formed from piezo-electric, electrostrictive or magnetostrictive actuators. In this embodiment, the conicalhousing comprises actuators, such that a conical diode device is formed. This embodiment is illustrated in FIG. 5, which shows a diode device 80, in which two electrodes 82 and 86 are separated by a conical piezo actuator 84. Piezo actuator 84 is used to control the distance between electrodes 82 and 86. A more detailed representation may be obtained by referring to FIG. 6, which shows in a diagrammatic form a diode device of the present invention, a first electrode 202, disposed on substrate 204, is attached to the end of actuator cone 90, and a second electrode 206, disposed on substrate 208, is attached to the other end of cone 90. The two electrodes are also connected to an electrical load or power supply 210 by means of wires 212 (210 is an electrical load when the device is a heat energy to electrical energy converter, and is a power supply when the device is a heat pump).

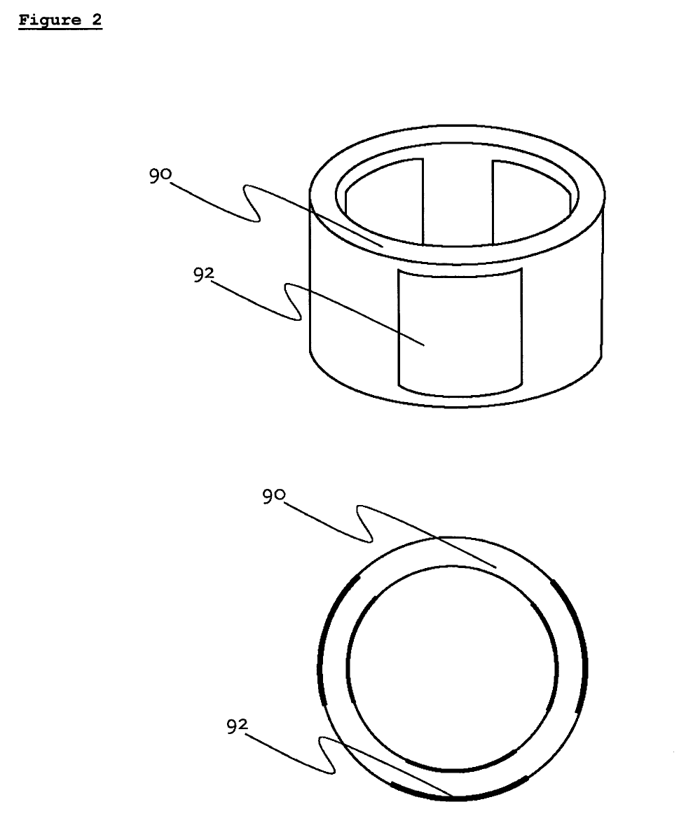

Actuator cone 90 has electrodes 92 disposed on its surface, as shown in FIG. 2 above, which are connected to controller 214 via wires 216. This controller sets the separation of electrodes 202 and 206. Electrodes 202 and 206 may also be connected to capacitance controller 218, which is able to assess the separation of the electrodes, and the separation of the electrodes may be accurately controlled via a feedback loop 220 to controller 214. Typically, the electrode separation is of the order of 0.1 to 100 nm. In a further embodiment, electrode 202 and 206 may be formed from a matching electrode pair precursor, which is a composite that may be separated along a boundary between two different composite layers into two matched electrodes, as disclosed in U.S. patent application Pub. Ser. No. 2003/0068431.

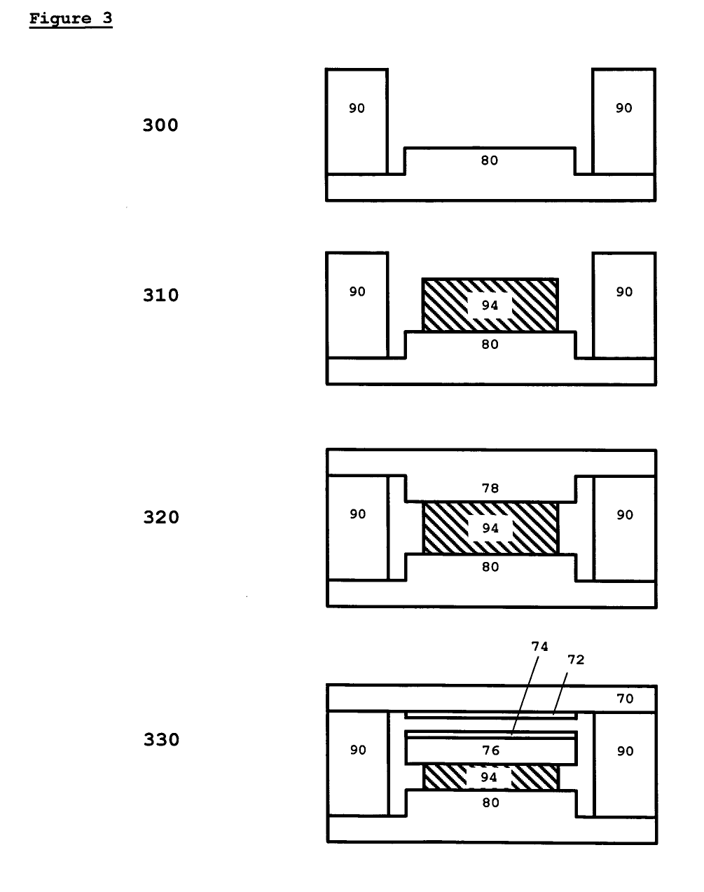

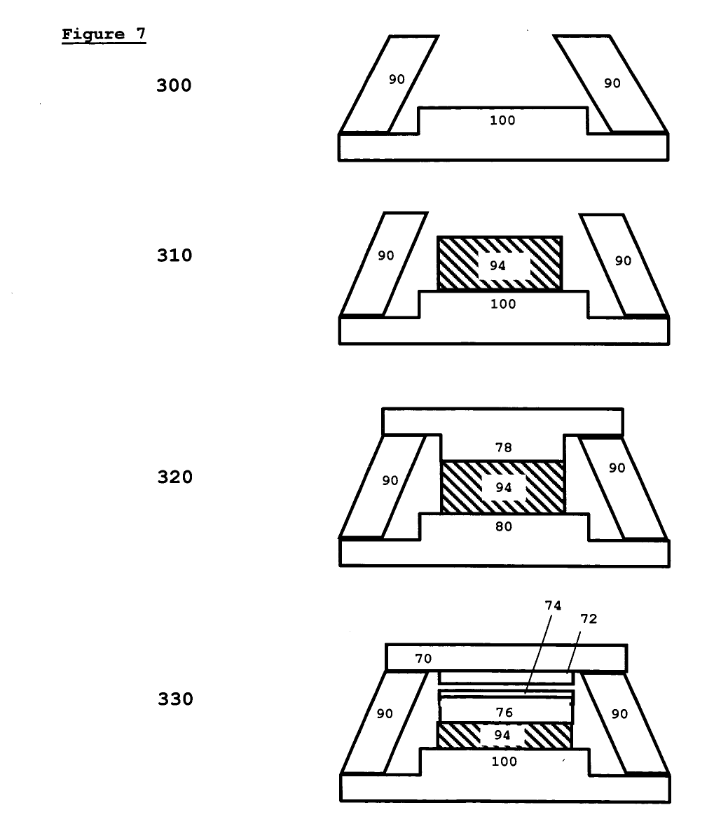

Actuators may also be utilized to separate a sandwich of the two electrodes, thus forming the device, as disclosed in WO03/083177 and shown in FIG. 3. This is exemplified in FIG. 7, which depicts a schematic process for making a cone-shaped diode device of the invention and also shows a preferred embodiment of a diode device of the present invention, in step 300 a first composite 100 is brought into contact with a polished end of a quartz cone 90. Composite 100 is preferably a molybdenum disc, which has a similar thermal expansion coefficient as quartz and can be bonded to quartz. In step 310, an electrically conducting paste 94, preferably silver paste, is applied to the upper surface of the molybdenum disc, as shown. In step 320, the polished silicon periphery of the upper composite 78 is contacted with the other polished end of the quartz cone 90. Composite 78 is preferably a matching electrode pair precursor, such as the composite shown in step 130 of WO99/13562 or U.S. Pat. No. 6,417,060, or is more preferably as described in this example, in which a layer of titanium 72 is deposited on substrate 70, and a layer of silver 74 is further deposited on the layer of titanium. A further layer of copper 76 is grown electrochemically on the layer of silver. Most preferably substrate 70 is a silicon wafer, and is polished at least around its periphery where it is in contact with cone 90. At the same time as the upper composite 78 is brought into contact with the end of the quartz tube, the electrically-conducting paste, preferably silver paste or liquid metal, contacts the upper composite as shown. High pressure is applied to this assemblage, which accelerates the chemical reaction between the polished silicon periphery of the composites and the polished ends of the quartz tube, bonding the polished surfaces to form the assemblage depicted in step 320. In step 330, the assemblage is heated, which causes the composite to open as shown, forming a pair of matching electrodes, 72 and 74. In some embodiments, step 330 comprises both heating the assemblage and applying a signal to the quartz tube to cause the composite to open as shown, forming two electrodes, 72 and 74.

The cone shape of the actuator causes the bond between the actuator and the substrates, composites or electrode pair precursors to remain strong. There is little risk that the temperature difference between the two electrodes, and therefore their growth at different rates, will weaken the hermetic seal.

This can be explained as follows: When the composite is closed, as in step 320, there is no temperature difference between the two electrodes. Once the composite is heated and a voltage is applied, as in step 330, the actuators push the electrodes apart. At this stage and throughout the time that the device is in operation, the electrodes remain at different temperatures. It is to be understood that the cold side grows more slowly than the hot side. As this happens, there will be increased force on the actuator cone, but this force will strengthen the seal, not weaken it.

When there is a very large temperature difference between the two sides, the hot side will have grown a large amount and may need to be pushed away from the cold side anyway to maintain the gap. This might also suggest that the piezos themselves, which expand anisotropically under temperature, would be less affected since the expansion would be consistent with their forces anyway.

A variety of techniques may be used to introduce the pairs of electrodes onto the conical element; by way of example only, and not to limit the scope of the invention, they may introduced by vacuum deposition, or by attaching a thin film using MEMS techniques. In a preferred embodiment, the actuating element is a piezo-electric actuator. In a particularly preferred embodiment, the actuator comprises quartz. The crystal orientation of the cone is preferably substantially constant, and may be aligned either parallel to, or perpendicular to the axis of the tube. An electric field may be applied to actuating element 90 via connecting wires in an arrangement similar to that shown in FIG. 6, which causes it to expand or contract longitudinally. An advantage of such a conical actuator is that it serves both as actuator and as housing simultaneously. Housing provides mechanical strength together with vacuum sealing. External mechanical shock/vibrations heat the external housing first, and are compensated immediately by the actuator.

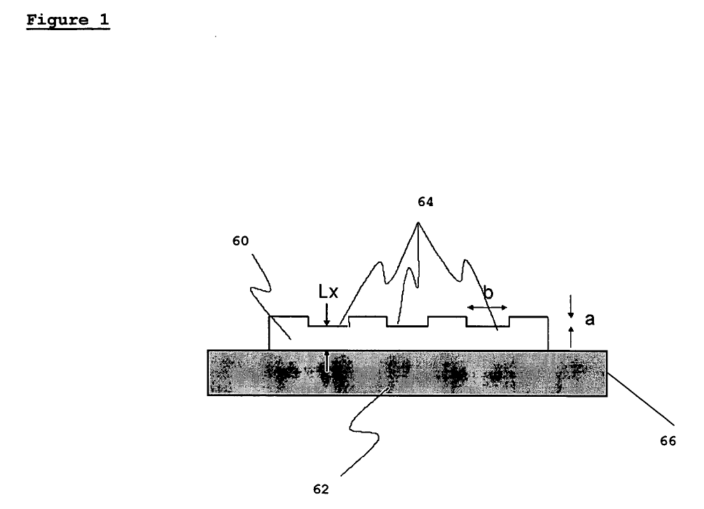

The electrodes utilized in the present invention may be formed from materials disclosed in diode device configurations of the prior art. For example, electrodes disclosed in Patent Number WO03/090245 may be utilized with relatively little modification. For example, a typical diode device may be constructed with electrodes made from copper and silicon, which are of different sizes even in previous models. This design further has the added benefits of a long heat flow path and a long piezo distance to provide a lot of throw, without greatly modifying the previous design. Furthermore, in a third embodiment, the diode device of the present invention is built with the modified electrode disclosed in WO03/083177 and shown in FIG. 1, which allows for a decrease in the work function of the electrode, and therefore an increase in the efficiency of the device. It is to be understood that the modified electrode 66 may be used as one or both electrodes in the diode device of the present invention. Electrodes of different lengths may be modified and then placed at a specified distance from each other and joined by slanting walls to form the conical diode device of the present invention.

Furthermore, electrodes having matching surfaces may be utilized. In this respect, when surface features of two facing surfaces of electrodes are described as ‘matching’, it means that where one surface has an indentation, the other surface has a protrusion and vice versa. Thus when matched, the two surfaces are substantially equidistant from each other throughout their operating range

It is to be understood that this is not a complete list of all possible applications, but serves to illustrate rather than limit the scope of the invention. It is to be further understood that many other applications of this invention are possible, and that it is likely that different combinations of the embodiments described may be used in constructing conical diode devices.

Accordingly, the invention is not limited to the embodiments described herein but should be considered in light of the claims that follow.

1. A diode device comprising:
a conical housing
a first electrode attached to one end of said conical housing;
a second electrode attached to an opposing end of said conical housing.

2. The diode device of claim 1 wherein said second electrode is significantly smaller than the first.

3. The diode device of claim 1 further comprising a hermetic seal between said first electrode and said conical housing, and a further hermetic seal between said second electrode and said conical housing.

4. The diode device of claim 3 wherein said first electrode is of a cooler temperature than said second electrode when the device is in operation.

5. The diode device of claim 3 wherein said first electrode contracts when the device is in operation.

6. The diode device of claim 3 wherein said second electrode expands when the device is in operation.

7. The diode device of claim 1, wherein said conical housing sustains a vacuum within the device.

8. The diode device of claim 1 wherein said diode device is selected from the group consisting of: thermionic converter, thermotunneling converter, vacuum diode heat pump, and photoelectric converter.

9. The diode device of claim 1 additionally comprising:
an electrical circuit connected to said electrodes;
a further pair of electrodes attached to an inner and outer face of said conical housing and attached to controlling circuitry;
wherein said housing consists of an actuating element whose length may be modified by a signal applied to said further pair of electrodes, whereby the magnitude of a distance separating said electrodes may be adjusted.

10. The diode device of claim 9 wherein said actuating element comprises a piezo-electric element.

11. The diode device of claim 10 wherein said piezo-electric element comprises quartz.

12. The diode device of claim 1 wherein said first and second electrodes comprise materials suitable for optimum thermionic or thermotunneling emmission.

13. The diode device of claim 1 wherein said first electrode and said second electrode comprise a matched pair of electrodes.

14. The diode device of claim 1 wherein said first electrode is in thermal contact with a heat source, and said second electrode is in thermal contact with a heat sink, and said electrical circuit connects said first and second electrodes to an electrical load.

15. The diode device of claim 1 wherein said first electrode is in thermal contact with a mass to be cooled, and said second electrode is in thermal contact with a heat sink, and said electrical circuit connects said first and second electrodes to a power supply.

16. The diode device of claim 1 wherein the magnitude of a distance separating said electrodes is between 0.1 and 100 nm.

17. The diode device of claim 1 wherein said first electrode and said second electrode comprise a substantially plane slab of a material having on one surface one or more indents of a depth approximately 5 to 20 times a roughness of said surface and a width approximately 5 to 15 times said depth.

18. The material of claim 17 in which walls of said indents are substantially perpendicular to one another.

19. The material of claim 17 in which walls of said indents are substantially sharp.

20. The material of claim 17 in which the Fermi energy level of electrons is increased compared to a material comprising a substantially plane slab of the same metal not having on one surface one or more indents.
